(19) United States
(12) Patent Application Publication
(10) Pub. No.: US 2023/0194982 A1
(43) Pub. Date: Jun. 22, 2023

(54) STAMP TREATMENT TO GUIDE SOLVENT REMOVAL DIRECTION AND MAINTAIN CRITICAL DIMENSION

(71) Applicant: Applied Materials, Inc., Santa Clara, CA (US)

(72) Inventors: Yingdong LUO, Newark, CA (US); Yongan XU, Santa Clara, CA (US); Kang LUO, San Jose, CA (US); Ludovic GODET, Sunnyvale, CA (US)

(21) Appl. No.: 18/091,525

(22) Filed: Dec. 30, 2022

Related U.S. Application Data
(63) Continuation of application No. PCT/US2022/053214, filed on Dec. 16, 2022.
(60) Provisional application No. 63/291,066, filed on Dec. 17, 2021.

(51) Int. Cl. G03F 7/00

(52) U.S. Cl. CPC G03F 7/0015; G03F 7/0002

(57) ABSTRACT

Embodiments described herein provide method a method of forming optical devices using nanoimprint lithography that maintains the critical dimension of the optical device structures. The method described herein accounts for lateral shrinkage of the solvent based resist during the cure process to maintain the critical dimension. The method includes disposing a stamp coating on a stamp having an inverse optical device pattern of inverse structures. The coating is disposed on sidewalls, inverse structure bottom, and inverse structure top of the inverse structures. The method includes etching the inverse structures such that the stamp coating remains on the sidewalls and is removed from the inverse structure top and bottom. The method further includes imprinting the stamp into an optical device material disposed and subjecting the imprintable optical device material to a cure process which transfers the optical device critical dimension to the optical device structures of the optical device pattern.

### RELATED APPLICATIONS

This application is a continuation of International Application No. PCT/US22/53214, international filing date Dec. 17, 2022, which claims priority to U.S. Provisional Application No. 63/291,066, filed Dec. 17, 2021, which are herein incorporated in their entirety by reference for all purposes.

### BACKGROUND

### Field

Embodiments of the present disclosure generally relate to display devices for augmented, virtual, and mixed reality. More specifically, embodiments described herein provide a method of forming an optical device using nanoimprint lithography that maintains the critical dimension of the optical device structures of the optical device.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is displaying a virtual image overlaid on an ambient environment. Optical devices including waveguide combiners, such as augmented reality waveguide combiners, and flat optical devices, such as metasurfaces, are used to assist in overlaying images. Generated light is propagated through an optical device until the light exits the optical device and is overlaid on the ambient environment. Fabricating optical device structures for use as an optical device or a master for nanoimprint lithography can be challenging. In particular, fabricating optical device structures having critical dimensions matched to a stamp can be challenging due to lateral shrinkage of the solvent based resist during the curing process. The lateral shrinkage of the solvent resulting in a reduction in critical dimension of the formed optical device structures from the solvent based resist.

Accordingly, what is needed in the art is a method of forming an optical device using nanoim print lithography that maintains the critical dimension of the optical device structures of the optical device.

### SUMMARY

In one embodiment, a method is provided. The method includes disposing a stamp coating on a stamp. The stamp having an inverse optical device pattern of inverse structures. The coating disposed on sidewalls, inverse structure bottom, and inverse structure top of each of the inverse structures. The inverse pattern having an inverse critical dimension between adjacent sidewalls of each of the inverse structures. The method includes etching the inverse structure bottom and inverse structure top with an etch process having an etch direction parallel to the sidewalls such that the stamp coating remains on the sidewalls and the stamp coating is removed from the inverse structure top and inverse structure bottom of each of the inverse structures, the stamp with the coating on the sidewalls having an optical device critical dimension between each coated sidewall, the optical device critical dimension to be transferred to optical device structures of an optical device pattern. The method further includes imprinting the stamp into an imprintable optical device material disposed on an optical device substrate, and subjecting the imprintable optical device material to a cure process, the cure process transferring the optical device critical dimension to the optical device structures of the optical device pattern formed by the cure process.

In another embodiment, a method is provided. The method includes forming a stamp from a master, the master comprising a master pattern such that the stamp molded from the master comprises an inverse optical device pattern. The method further includes disposing a stamp coating on the stamp. The stamp having the inverse optical device pattern of inverse structures. The coating disposed on sidewalls, inverse structure bottom, and inverse structure top of each of the inverse structures. The inverse pattern having an inverse critical dimension between adjacent sidewalls of each of the inverse structures. The method includes etching the inverse structure bottom and inverse structure top with an etch process having an etch direction parallel to the sidewalls such that the stamp coating remains on the sidewalls and the stamp coating is removed from the inverse structure top and inverse structure bottom of each of the inverse structures, the stamp with the coating on the sidewalls having an optical device critical dimension between each coated sidewall, the optical device critical dimension to be transferred to optical device structures of an optical device pattern. The method further includes imprinting the stamp into an imprintable optical device material disposed on an optical device substrate, and subjecting the imprintable optical device material to a cure process, the cure process transferring the optical device critical dimension to the optical device structures of the optical device pattern formed by the cure process.

In another embodiment, a method is provided. The method includes disposing a stamp coating on a stamp. The stamp comprises an inverse optical device pattern of inverse structures. The coating is disposed on sidewalls, inverse structure bottom, and inverse structure top of each of the inverse structures. The inverse pattern comprises an inverse critical dimension between adjacent sidewalls of each of the inverse structures. The sidewalls have a slant angle relative to the surface normal of the optical device substrate. The method includes etching the inverse structure bottom and inverse structure top with an etch process having an etch direction parallel to the sidewalls such that the stamp coating remains on the sidewalls and the stamp coating is removed from the inverse structure top and inverse structure bottom of each of the inverse structures, the stamp with the coating on the sidewalls having an optical device critical dimension between each coated sidewall, the optical device critical dimension to be transferred to optical device structures of an optical device pattern. The method further includes imprinting the stamp into an imprintable optical device material disposed on an optical device substrate, and subjecting the imprintable optical device material to a cure process, the cure process transferring the optical device critical dimension to the optical device structures of the optical device pattern formed by the cure process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

The disclosure contains at least one drawing executed in color. Copies of this disclosure with color drawings will be provided to the Office upon request and payment of the necessary fee. As the color drawings are being filed electronically via EFS-Web, only one set of the drawings is submitted.

FIG. 1A is a perspective, frontal view of an optical device according to embodiments described herein.

FIG. 1B is a schematic, top view of an optical device according to embodiments described herein.

FIG. 2A-2B are schematic, cross-sectional views of a plurality of optical devices structures according to embodiments described herein.

FIG. 3 is a flow diagram of a method of forming an optical device according to embodiments described herein.

FIGS. 4A-4H are schematic, cross-sectional views of a portion of an optical device substrate during a method of forming an optical device according to embodiments described herein.

FIG. 5A is a schematic, cross-sectional view of an optical device structure containing a solvent to embodiments described herein.

FIG. 5B is a schematic, cross-sectional view of an optical device structure after a curing process according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide method a method of forming an optical device using nanoimprint lithography that maintains the critical dimension of the optical device structures of the optical device. The method described herein accounts for lateral shrinkage of the solvent based resist during the cure process to maintain the critical dimension. The method includes disposing a stamp coating on a stamp having an inverse optical device pattern of inverse structures. The coating is disposed on sidewalls, inverse structure bottom, and inverse structure top of each of the inverse structures. The method includes etching the inverse structure bottom and inverse structure top with an etch such that the stamp coating remains on the sidewalls and is removed from the inverse structure top and inverse structure bottom. The method further includes imprinting the stamp into an imprintable optical device material disposed on an optical device substrate. The optical device material comprises a solvent-based resist, such as a sol-gel, which requires the removal of solvent. The method further comprises subjecting the imprintable optical device material to a cure process which transfers the optical device critical dimension to the optical device structures of the optical device pattern formed by the cure process. The stamp comprises an absorbable material, such that during the cure process, the solvent from the imprintable optical device material is absorbed by the stamp or vaporized. This stamp absorption and/or solvent vaporization results in vertical shrinkage of the optical device structures, but maintains the critical dimension.

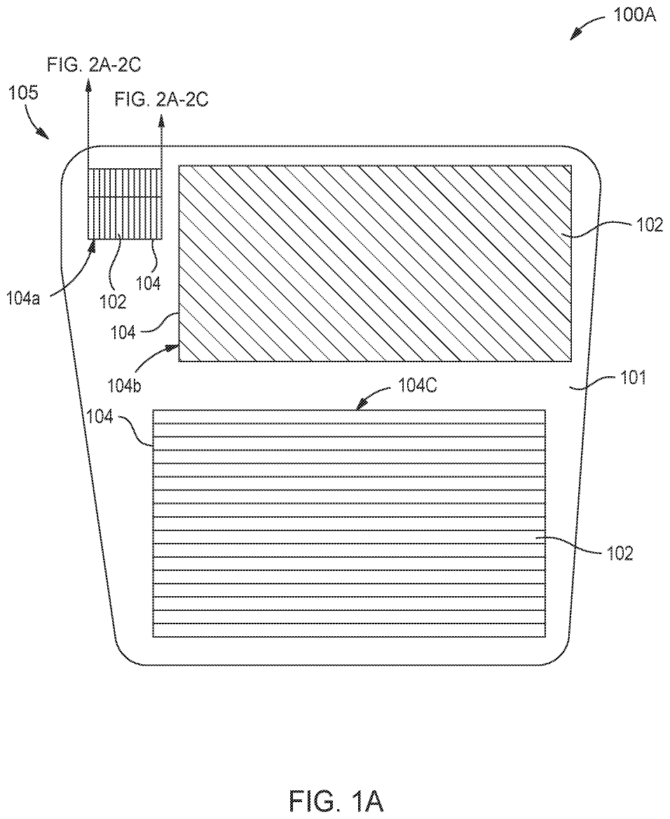

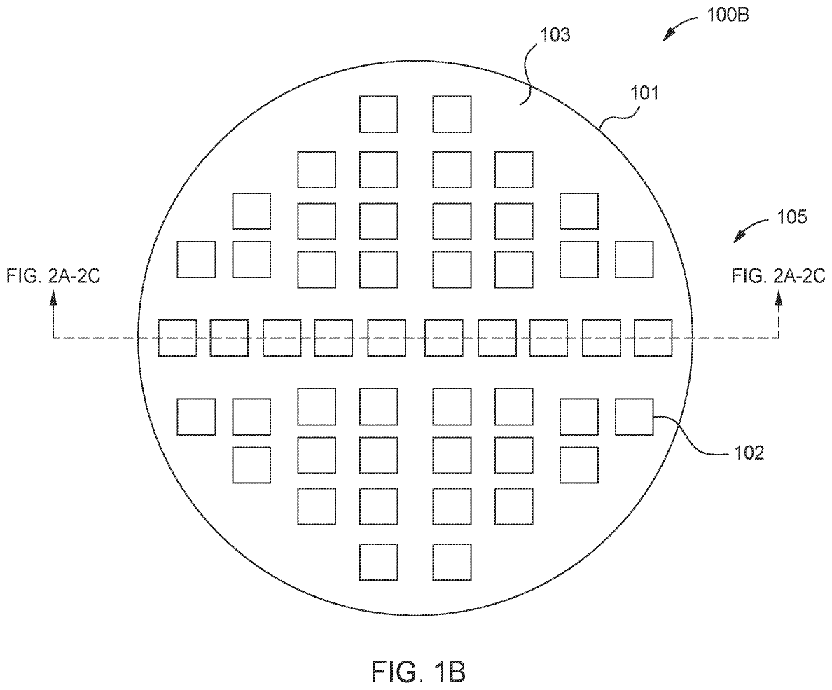

FIG. 1A is a perspective, frontal view of an optical device 100A. FIG. 1B is a schematic, top view of an optical device 100B. It is to be understood that the optical devices 100A and 100B described below are exemplary optical devices. In one embodiment, which can be combined with other embodiments described herein, the optical device 100A is a waveguide combiner, such as an augmented reality waveguide combiner. In another embodiment, which can be combined with other embodiments described herein, the optical device 100B is a flat optical device, such as a metasurface. The optical devices 100A and 100B include a plurality of optical device structures 102 disposed on a surface 103 of an optical device substrate 101. The optical device structures 102 may be nanostructures having sub-micron dimensions, e.g., nano-sized dimensions. In one embodiment, which can be combined with other embodiments described herein, regions of the optical device structures 102 correspond to one or more gratings 104, such as a first grating 104a, a second grating 104b, and a third grating 104c. In one embodiment, which can combined with other embodiments described herein, the optical devices 100A is a waveguide combiner that includes at least the first grating 104a corresponding to an input coupling grating and the third grating 104c corresponding to an output coupling grating. The waveguide combiner according to the embodiment, which can be combined with other embodiments described herein, includes the second grating 104b corresponding to an intermediate grating. While FIG. 1B depicts the optical device structures 102 as having square or rectangular shaped cross-sections, the cross-sections of the optical device structures 102 may have other shapes including, but not limited to, circular, triangular, elliptical, regular polygonal, irregular polygonal, and/or irregular shaped cross-sections. In some embodiments, which can be combined with other embodiments described herein, the cross-sections of the optical device structures 102 on a single optical device 100B are different.

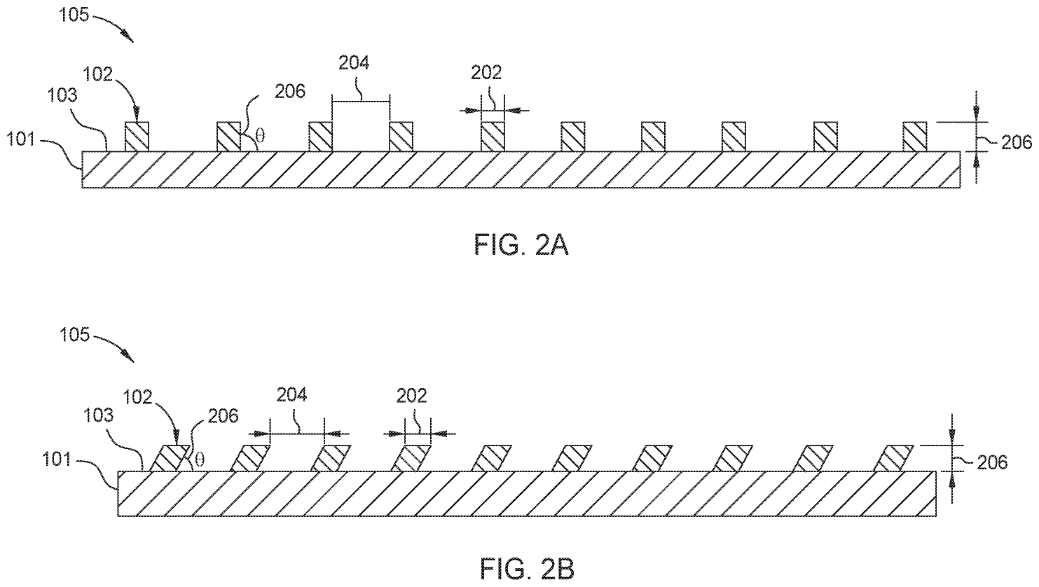

FIGS. 2A-2B are schematic, cross-sectional views of a plurality of optical device structures 102. FIGS. 2A-2B are a portion 105 of the optical device 100A or the optical device 100B. The portion 105 of the optical devices 100A and 100B include the plurality of optical device structures 102 disposed on a surface 103 of an optical device substrate 101. In one embodiment, which can be combined with other embodiments described herein, the plurality of optical device structures 102 correspond to the first grating 104a, the second grating 104b, or the third grating 104c of the optical device 100A. The plurality of optical device structures 102 are formed at a device angle θ. The device angle θ is the angle between the surface 103 of the optical device substrate 101 and the sidewall 406 of the optical device structure 102. As shown in FIGS. 2A, the plurality of optical devices 102 are vertical, i.e., the device angle θ is 90 degrees. As shown in FIGS. 2B, the plurality of optical devices 102 are angled relative to the surface 103 of the substrate 101. I.e., plurality of optical device structures 102 have a slant angle relative to the surface normal of the optical device substrate 101. In one embodiment, which can be combined with other embodiments described herein, each respective device angle θ for each optical device structure 102 is substantially equal. In another embodiment, which can be combined with other embodiments described herein, at least one respective device angle θ of the plurality of optical device structures 102 is different than another device angle θ of the plurality of optical device structures 102.

Each optical device structure of the plurality of optical device structures 102 has a critical dimension 202. The critical dimension 202 is less than 1 micrometer (μm). I.e., the optical device structures 102 may be nanostructures having sub-micron dimensions, e.g., nano-sized dimensions. The critical dimension 202 corresponds to a width or a diameter of each optical device structure 102, depending on the cross-section of the optical device structure 102. In one embodiment, which can be combined with other embodiments described herein, at least one critical dimension 202 may be different from another critical dimension 202. In another embodiment, which can be combined with other embodiments described herein, each critical dimension of the plurality of optical device structures 102 is substantially equal to each other.

The optical device structures 102 have a linewidth 204 defined as the distance between adjacent angled optical device structures 102. As shown in FIGS. 2A and 2B, the linewidth 204 of each of the adjacent optical device structures 102 are substantially equal to each other. In other embodiments, at least one linewidth 204 of adjacent optical device structures 102 is different from the linewidth 204 of other adjacent optical device structures 102 of the portion. Each optical device structure 102 of the plurality of optical device structures 102 has an aspect ratio defined as the ratio of the linewidth 204 to the depth 206. Any of the embodiments described herein may include two or more adjacent optical device structures 102 with the same linewidth 204 or two or more adjacent optical device structures 102 with a different critical dimension 202.

Each optical device structure 102 of the plurality of optical device structures 102 has a depth 206. In one embodiment, which can be combined with other embodiments described herein, at least one depth 206 of the plurality of optical device structures 102 is different that the depth 206 of the other optical device structures 102. In another embodiment, which can be combined with other embodiments described herein, each depth 206 of the plurality of optical device structures 102 is substantially equal to the adjacent optical device structures 102.

The optical device structures 102 are formed from an imprintable optical device material. The imprintable optical device material is configured to be imprintable by a stamp prior to a cure process. The imprintable optical device material contains a plurality of nanoparticles and one or more solvents (such as sol-gel or nanoparticle-containing resists). The imprintable optical device material may additionally include at least one of a surface ligand, an additive, and an acrylate. The cure process removes the solvent from the optical device material via stamp absorption or solvent vaporization. The optical device structures formed from the imprintable optical device material after curing include the nanoparticles, and in some embodiments the nanoparticles and remaining cured material. In some embodiments, which can be combined with other embodiments described herein, the optical device structures 102 may have a refractive index between about 1.35 and about 2.70. In other embodiments, which can be combined with other embodiments described herein, the optical device structures 102 may have a refractive index between about 3.5 and about 4.0. The imprintable optical device material of the optical device structures 102 includes, but is not limited to, one or more of silicon oxycarbide (SiOC), titanium dioxide (TiO₂), silicon dioxide (SiO₂), vanadium (IV) oxide (VOx), aluminum oxide (Al₂O₃), aluminum-doped zinc oxide (AZO), indium tin oxide (ITO), tin dioxide (SnO₂), zinc oxide (ZnO), tantalum pentoxide (Ta₂O₅), silicon nitride (Si₃N₄), zirconium dioxide (ZrO₂), niobium oxide (Nb₂O₅), cadmium stannate (Cd₂SnO₄), cerium dioxide (CeO2), silver (Ag) nanoparticles, gold (Au) nanoparticles, cadmium selenide (CdSe), cadmium telluride (CdTe), mercury telluride (HgTe), zinc selenide (ZnSe), silver-indium-gallium-sulfur (Ag—In—Ga—S) composite nanoparticle, silver-indium-sulfur (Ag—In—S), indium phosphide (InP), gallium phosphide (GaP), ZnSeS, lead sulfide (PbS), lead selenide (PbSe), zinc sulfide (ZnS), molybdenum disulfide (MoS₂), tungsten disulfide (WS₂), silicon carbide (SiC), or silicon carbon-nitride (SiCN) containing materials.

The optical device substrate 101 may also be selected to transmit a suitable amount of light of a desired wavelength or wavelength range, such as one or more wavelengths from about 100 to about 3000 nanometers. Without limitation, in some embodiments, the optical device substrate 101 is configured such that the optical device substrate 101 transmits greater than or equal to about 50% to about 100%, of an infrared to ultraviolet region of the light spectrum. The optical device substrate 101 may be formed from any suitable material, provided that the optical device substrate 101 can adequately transmit light in a desired wavelength or wavelength range and can serve as an adequate support for the optical devices 100A and 100B described herein. In some embodiments, which can be combined with other embodiments described herein, the material of optical device substrate 101 has a refractive index that is relatively low, as compared to the refractive index of the material of the plurality of angled optical device structures 102. Optical device substrate selection may include optical device substrates of any suitable material, including, but not limited to, amorphous dielectrics, non-amorphous dielectrics, crystalline dielectrics, silicon oxide, polymers, and combinations thereof. In some embodiments, which may be combined with other embodiments described herein, the optical device substrate 101 includes a transparent material. In one embodiment, which may be combined with other embodiments described herein, the optical device substrate 101 is transparent with absorption coefficient smaller than 0.001. Suitable examples may include silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), sapphire, or combinations thereof.

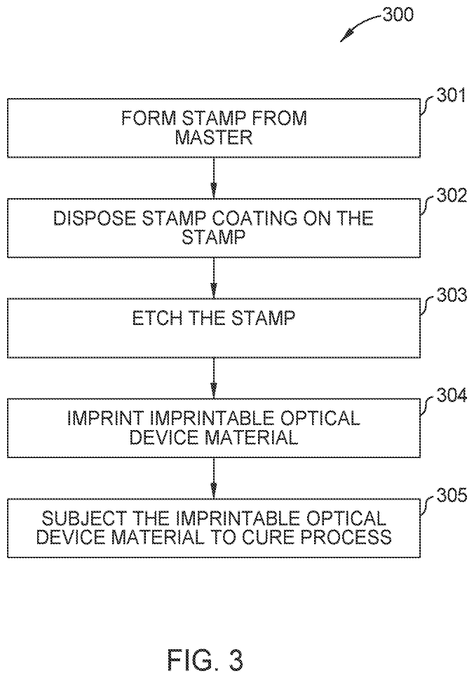

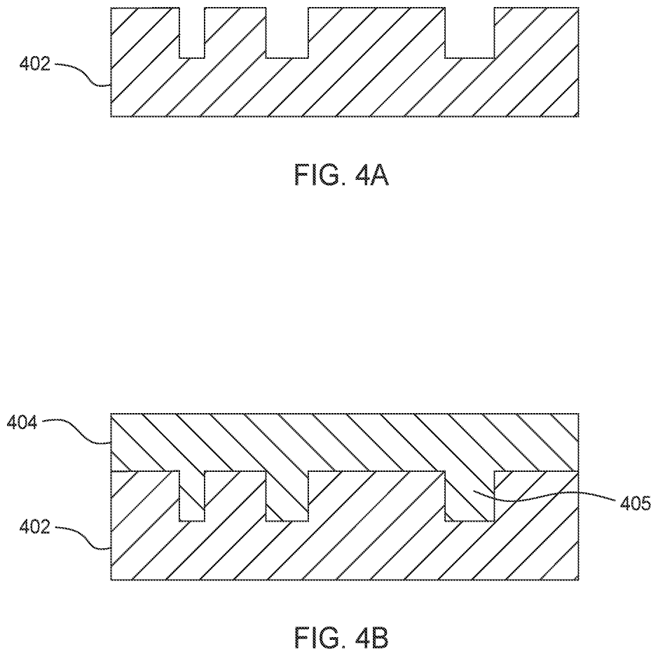

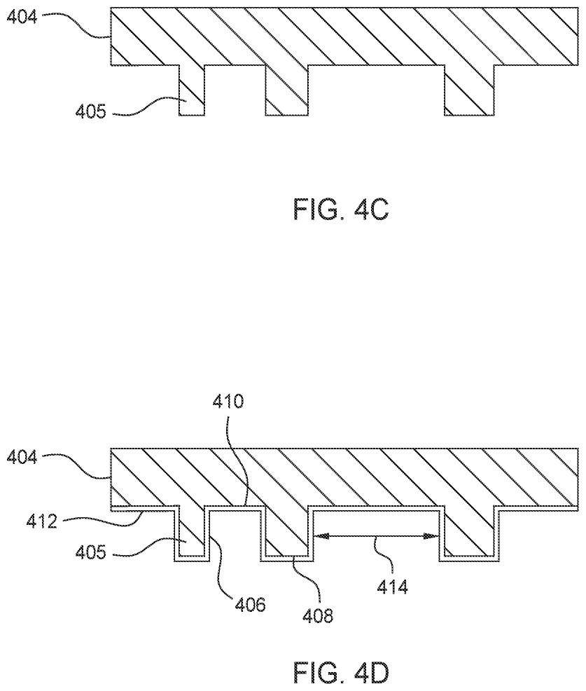

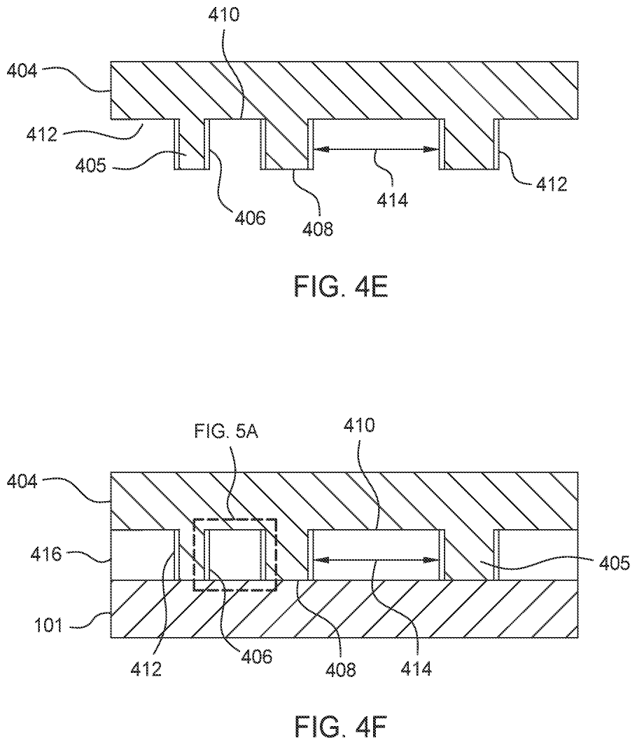

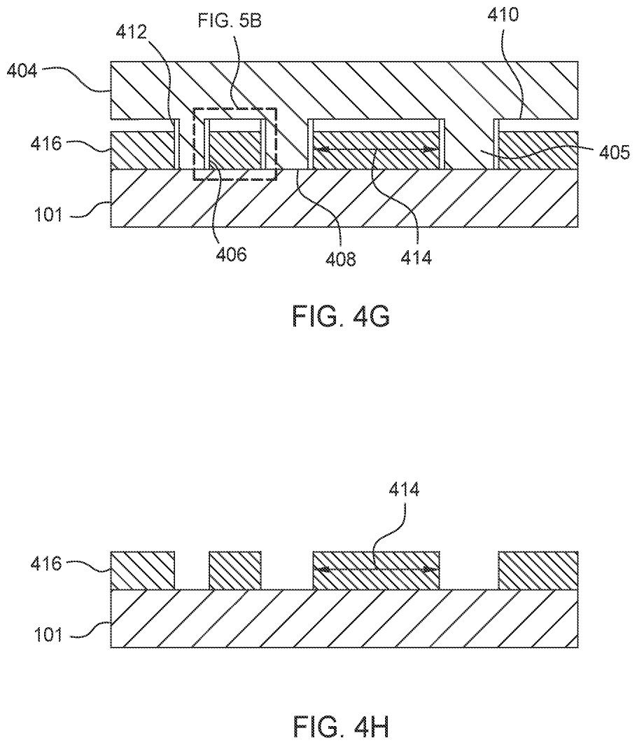

FIG. 3 is a flow diagram of a method 300 of forming an optical device. The method 300 is performed with a nanoimprint lithography process that maintains the critical dimension of the optical device structures, as shown in FIGS. 4A-4H. FIGS. 4A-4H are schematic, cross-sectional views of a portion 105 of an optical device substrate 101 during a method 300 of forming an optical device. In one embodiment, which can be combined with other embodiments described herein, the portion 105 may correspond to a portion or a whole surface of the optical device substrate 101 of a flat optical device, such as the optical device 1008. In another embodiment, which can be combined with other embodiments described herein, the portion 105 may correspond to a portion or a whole surface of the optical device substrate 101 of a waveguide combiner, such as the optical device 100A. For example, the portion 105 corresponds to the first grating 104a, the second grating 104b, or the third grating 104c of the optical device 100A to be formed.

At operation 301, as shown in FIGS. 4A-4C, a stamp 404 is formed from a master 402. The master 402 comprises a master pattern such that the stamp 404 molded from the master 402 comprises an inverse optical device pattern 403. The stamp 404 may be made from a semi-transparent material, such as fused silica or polydimethylsiloxane (PDMS) material. Alternatively, the stamp 404 may be made from a transparent material, such as a glass material or a plastic material. The semi-transparent or alternatively transparent material composition of the stamp 404 allows the nanoimprint resist to be cured by exposure to electromagnetic radiation, such as infrared (IR) radiation or ultraviolet (UV) radiation. The stamp 404 comprises a polymer which can absorb solvents. For example, the stamp 404 may comprise a porous polymer. Suitable examples include silicone, polyacrylate, polymethacrylate, polyurethane, and the copolymers. Once molded from the master 402, the stamp 404 is cured and released, as shown in FIG. 4C. The resulting stamp 404 comprises a plurality of inverse structures 405 that corresponds to the inverse optical device pattern.

At operation 302, as shown in FIG. 4D, a coating 412 is disposed on the stamp 404. In particular, the coating 412 is disposed on sidewalls 406, inverse structure bottom 408, and inverse structure top 410 of each of the inverse structures. The coating 412 may be disposed via an atomic layer deposition, chemical vapor deposition, or physical vapor deposition process. The inverse pattern has an inverse critical dimension 414 between adjacent sidewalls 406 of each of the inverse structures 405. After deposition of the coating 412, the critical dimension 414 matches with the desired critical dimension 414. The coating 412 may comprise amorphous silicon, polysilicon, aluminum oxide (Al₂O₃), silicon nitride (Si₃N₄), silicon dioxide (SiO₂), graphene, or combinations thereof.

At operation 303, the inverse structure bottom 408 and inverse structure top 410 are etched with an etch process having an etch direction parallel to the sidewalls 406. In some embodiments, wherein the inverse structures 405 are angled, the etch process may be an angled etch process. After operation 303, the stamp coating 412 remains on the sidewalls 406 and is removed from the inverse structure top 408 and inverse structure bottom 410 of each of the inverse structures, as depicted in FIG. 4E. The stamp 404 with the coating 412 on the sidewalls 406 has an optical device critical dimension 414 between each coated sidewall 406. The optical device critical dimension 414 is transferred to the optical device structures of an optical device pattern.

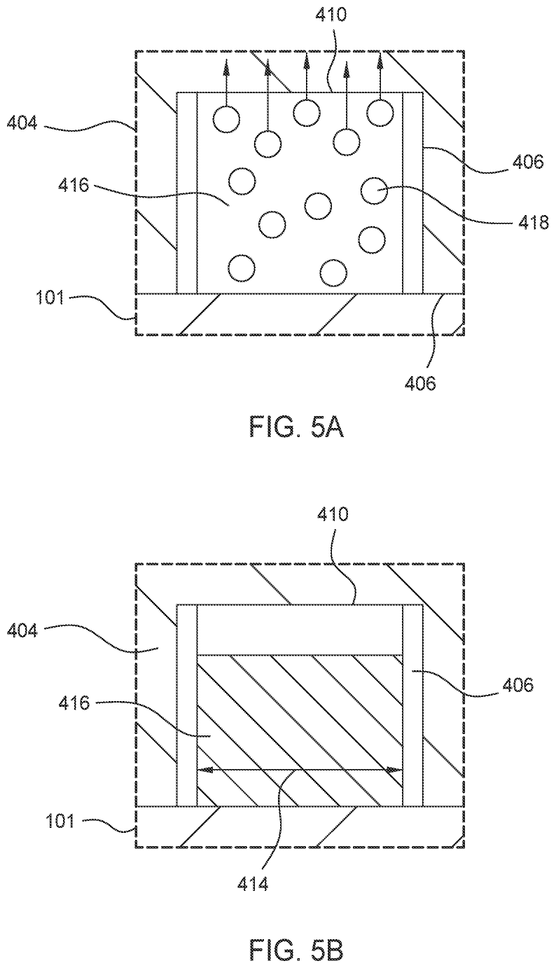

At operation 304, as shown in FIGS. 4F and 5A, the stamp 404 is imprinted into an imprintable optical device material 416 disposed on an optical device substrate 101. FIG. 5A is a schematic, cross-sectional view of the optical device material 416 containing solvent 418. The optical device material 416 comprises a solvent-based resist, such as a sol-gel or a nanoparticle-containing resist.

At operation 304, as shown in FIGS. 4G and 5B, the imprintable optical device material 416 and stamp 404 are subjected to a cure process. The cure process transfers the optical device critical dimension 414 to the optical device structures of the optical device pattern. The cure process may be a thermal and/or UV process. FIG. 5B is a schematic, cross-sectional view of the optical device structure after a curing process. Curing the optical device material 416 prompts the removal of solvent 418 from the optical device material 416 by stamp 404 absorption. The solvent 418 is able to flow vertically into the stamp 404 for absorption, through the uncoated inverse top structure 410. The coating disposed the sidewall 406 prevents lateral solvent flow, resulting in critical dimension 414 maintenance. If vertical shrinkage occurs, the critical dimension 414 is maintained to ensure the pattern fidelity of the optical device 100A, 100B.

When the stamp 404 is released, as shown in FIG. 4H, the resulting optical device structures have maintained the optical device critical dimension 414. In one embodiment, the stamp 404 can be mechanically released as the stamp 404 may be coated with a mono-layer of anti-stick surface treatment coating, such as a fluorinated coating. In another embodiment, the stamp 404 may comprise a water soluble material, such as a polyvinyl alcohol (PVA) material, that is water soluble in order for the stamp 404 to be released by dissolving the stamp 404 in water.

In summation, methods of forming an optical device using nanoimprint lithography that maintains the critical dimension of the optical device structures of the optical device are described herein. During the cure process, the solvent from the solvent-based resist is removed by stamp absorption. Coating the sidewalls of the stamp to prevent lateral solvent flow maintains the critical dimension of the optical device structures. Therefore, the quality of the optical device is improved due to the control of the critical dimension

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
disposing a stamp coating on a stamp, the stamp having an inverse optical device pattern of inverse structures, the coating disposed on sidewalls, inverse structure bottom, and inverse structure top of each of the inverse structures, the inverse pattern having an inverse critical dimension between adjacent sidewalls of each of the inverse structures;
etching the inverse structure bottom and inverse structure top with an etch process having an etch direction parallel to the sidewalls such that the stamp coating remains on the sidewalls and the stamp coating is removed from the inverse structure top and inverse structure bottom of each of the inverse structures, the stamp with the coating on the sidewalls having an optical device critical dimension between each coated sidewall, the optical device critical dimension to be transferred to optical device structures of an optical device pattern;
imprinting the stamp into an imprintable optical device material disposed on an optical device substrate; and
subjecting the imprintable optical device material to a cure process, the cure process transferring the optical device critical dimension to the optical device structures of the optical device pattern formed by the cure process.

2. The method of claim 1, wherein the optical device substrate comprises silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), sapphire, or combinations thereof.

3. The method of claim 1, wherein the imprintable optical device material comprises a nanoim print resist including a solvent and nanoparticles.

4. The method of claim 1, wherein the sidewalls have a slant angle relative to a surface normal of the optical device substrate.

5. The method of claim 4, wherein the etch process is an angled etch process.

6. The method of claim 1, wherein the stamp coating comprises amorphous silicon, polysilicon, aluminum oxide (Al₂O₃), silicon nitride (Si₃N₄), silicon dioxide (SiO₂), graphene, or combinations thereon.

7. The method of claim 1, wherein the stamp coating is disposed via atomic layer deposition, chemical vapor deposition, or physical vapor deposition.

8. The method of claim 1, wherein each of the optical device structures have a critical dimension less than 1 micrometer.

9. The method of claim 1, wherein the each of the optical device structures have a refractive index between 1.35 and 4.0.

10. A method, comprising:
forming a stamp from a master, the master comprising a master pattern such that the stamp molded from the master comprises an inverse optical device pattern;
disposing a stamp coating on the stamp, the stamp having the inverse optical device pattern of inverse structures, the coating disposed on sidewalls, inverse structure bottom, and inverse structure top of each of the inverse structures, the inverse pattern having an inverse critical dimension between adjacent sidewalls of each of the inverse structures;
etching the inverse structure bottom and inverse structure top with an etch process having an etch direction parallel to the sidewalls such that the stamp coating remains on the sidewalls and the stamp coating is removed from the inverse structure top and inverse structure bottom of each of the inverse structures, the stamp with the coating on the sidewalls having an optical device critical dimension between each coated sidewall, the optical device critical dimension to be transferred to optical device structures of an optical device pattern;
imprinting the stamp into an imprintable optical device material disposed on an optical device substrate; and
subjecting the imprintable optical device material to a cure process, the cure process transferring the optical device critical dimension to the optical device structures of the optical device pattern formed by the cure process.

11. The method of claim 10, wherein the optical device substrate comprises silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), sapphire, or combinations thereof.

12. The method of claim 10, wherein the imprintable optical device material comprises a nanoim print resist including a solvent and nanoparticles.

13. The method of claim 12, wherein the etch process is an angled etch process.

14. The method of claim 10, wherein the stamp coating comprises amorphous silicon, polysilicon, aluminum oxide (Al₂O₃), silicon nitride (Si₃N₄), silicon dioxide (SiO₂), graphene, or combinations thereon.

15. The method of claim 10, wherein the stamp coating is disposed via atomic layer deposition, chemical vapor deposition, or physical vapor deposition.

16. A method, comprising:
disposing a stamp coating an a stamp, wherein:
the stamp comprises an inverse optical device pattern of inverse structures;
the coating is disposed on sidewalls, inverse structure bottom, and inverse structure top of each of the inverse structures;
the inverse pattern comprises an inverse critical dimension between adjacent sidewalls of each of the inverse structures; and
the sidewalls have a slant angle relative to a surface normal of an optical device substrate;
etching the inverse structure bottom and inverse structure top with an etch process having an etch direction parallel to the sidewalls such that the stamp coating remains on the sidewalls and the stamp coating is removed from the inverse structure top and inverse structure bottom of each of the inverse structures, the stamp with the coating on the sidewalls having an optical device critical dimension between each coated sidewall, the optical device critical dimension to be transferred to optical device structures of an optical device pattern;
imprinting the stamp into an imprintable optical device material disposed on the optical device substrate; and
subjecting the imprintable optical device material to a cure process, the cure process transferring the optical device critical dimension to the optical device structures of the optical device pattern formed by the cure process.

17. The method of claim 16, wherein the imprintable optical device material comprises a nanoimprint resist including a solvent and nanoparticles

18. The method of claim 16, wherein the etch process is an angled etch process.

19. The method of claim 16, wherein the stamp coating comprises amorphous silicon, polysilicon, aluminum oxide (Al₂O₃), silicon nitride (Si₃N₄), silicon dioxide (SiO₂), graphene, or combinations thereon.

20. The method of claim 16, wherein the stamp coating is disposed via atomic layer deposition, chemical vapor deposition, or physical vapor deposition.
